(19) United States
(12) Patent Application Publication
(10) Pub. No.: US 2026/0311026 A1
(43) Pub. Date: Oct. 8, 2026

(54) SYSTEMS, METHODS, AND DEVICES FOR PROVIDING ULTRA-LOW LATENCY COMMUNICATION LINKS

(71) Applicant: JPMORGAN CHASE BANK, N.A., New York, NY (US)

(72) Inventors: Andrew CONRAD, Stamford, CT (US); Jude SEEBER, New York, NY (US); Taylor SHIELDS, New York, NY (US); Omar AMER, New York, NY (US)

(21) Appl. No.: 19/438,354

(22) Filed: Dec. 31, 2025

Related U.S. Application Data
(60) Provisional application No. 63/782,777, filed on Apr. 3, 2025.

(51) Int. Cl. G06N 10/60; G06N 10/70; H03M 1/00

(52) U.S. Cl. CPC G06N 10/60; G06N 10/70; H03M 1/001

(57) ABSTRACT

An electronic device may include programmable logic that generates a first digital signal; an encoder that encodes the first digital signal as a positive amplitude and a negative amplitude using a first RF waveform that is selected based on a value of the first digital signal and comprises an initial calibration pulse; an output port that outputs the encoded first analog signal to a second electronic device over a low-latency connection; an input port that receives an encoded second analog signal from the second electronic device over the low-latency connection; a decoder that extracts the encoded second digital signal into a second digital signal by measuring the encoded second digital signal and a received calibration pulse in the encoded second digital signal; and an input/output interface provides the second digital signal to a system that is configured to execute an action based on the second digital signal.

### RELATED APPLICATIONS

This application claims priority to, and the benefit of, U.S. Provisional Patent Application Ser. No. 63/782,777, filed Apr. 3, 2025, the disclosure of which is hereby incorporated, by reference, in its entirety.

### BACKGROUND OF THE INVENTION

### 1. Field of the Invention

Embodiments relate to systems, methods, and devices for providing ultra-low latency communication links.

### 2. Description of the Related Art

Quantum protocols, such as Quantum Position Verification (QPV), require ultra-low latency communication as part of the process to certify the geographical location of an entity. In general, ultra-low latency is typically measured in nanoseconds. Existing communication approaches, such as fiber-optic cable or coaxial cable, provide communication speeds slightly slower than the speed of light and cables often do not follow straight lines, both of which can add unacceptable latency. Wireless communication offers the ability for radio signals to travel approximately at the speed of light through air and potentially in a direct line of sight. Commercially available point-to-point radio links, however, have transmission and reception latencies that are too high to be of practical value for QPV.

### SUMMARY OF THE INVENTION

Systems, methods, and electronic devices for providing ultra-low latency communication links are disclosed. In one embodiment, an electronic device may include programmable logic that is configured to generate a first digital signal; an encoder that is configured to encode the first digital signal using a first RF waveform, wherein the first RF waveform is selected based on a value of the first digital signal and comprises an initial calibration pulse, and the first digital signal is encoded with a positive amplitude and a negative amplitude; a digital-to-analog converter that is configured to convert the encoded first digital signal to an encoded first analog signal; an output port that is configured to output the encoded first analog signal to a second electronic device over a low-latency connection; an input port that is configured to receive an encoded second analog signal from the second electronic device over the low-latency connection; an analog-to-digital converter that is configured to convert the encoded second analog signal to an encoded second digital signal; a decoder that is configured to extract the encoded second digital signal into a second digital signal by measuring the encoded second digital signal and a received calibration pulse in the encoded second digital signal; and an input/output interface that is configured to provide the second digital signal to a system that is configured to execute an action based on the second digital signal.

In one embodiment, the electronic device may include a field programmable gate array, or a programmable logic device, application specific integrated chip.

In one embodiment, the programmable logic may be further configured to generate a clock signal and to modulate the clock signal with a pulse per second (PPS) signal by modifying a duty cycle of the clock signal once per second, and to communicate the modulated clock signal to another electronic device.

In one embodiment, the duty cycle may be modified by increasing the duty cycle.

In one embodiment, the PPS signal indicates that a prover is ready to start a quantum position verification round.

In one embodiment, the electronic device may also include at least one antenna that may be configured to receive the encoded first analog signal from the output port and to communicate the encoded first analog signal over the low-latency connection, and to receive the encoded second analog signal from the low-latency connection and provide the encoded second analog signal to the input port.

In one embodiment, the electronic device may also include an error correction module that may be configured to detect an error in the encoded first digital signal by comparing the positive amplitude and the negative amplitude of the encoded first digital signal; and/or to detect an error in the encoded second digital signal by comparing a positive amplitude and the negative amplitude of the encoded second digital signal.

In one embodiment, the low-latency connection may include a hollow core fiber and/or a coaxial RF cable.

In one embodiment, the system comprises a quantum source, and the system executes an action with the second digital signal by executing a quantum state transformation and/or a quantum measurement.

According to another embodiment, a method may include: communicating, by a prover electronic device and to a plurality of verifier electronic devices, a prover claimed location, wherein the prover claimed location is untrusted, wherein each of the plurality of verifier electronic devices may be configured to calculate a timing offset based on a location of the verifier electronic device and the prover claimed location; communicating, by the prover electronic device and to the plurality of verifier electronic devices, a request for challenge messages; receiving, by the prover electronic device and from each of the plurality of verifier electronic devices, a challenge message, wherein each of the plurality of verifier electronic devices may be configured to communicate their challenge messages to prover electronic device using the timing offsets so that the challenge messages arrive at the same time; executing, by the prover electronic device, an action using the challenge messages, resulting in an answer; and communicating, by the prover electronic device, the answer to the plurality of verifier electronic devices, wherein each of the plurality of verifier electronic devices may be configured to verify the answer and to verify a time of arrival of the answer.

In one embodiment, the action may include hashing contents of the challenge messages.

In one embodiment, the action may include measuring a quantum state of a quantum system using contents of the challenge messages.

In one embodiment, the time of arrival may be based on a distance between the location of each of the plurality of verifier electronic devices and the prover claimed location.

According to another embodiment, a method may include: generating, by a prover electronic device, a modulated clock signal with a pulse per second (PPS) signal by modifying a duty cycle of a clock signal once per second; communicating, by the prover electronic device, the modulated clock signal to a plurality of verifier electronic devices; communicating, by the prover electronic device and to the plurality of verifier electronic devices, a prover claimed location, wherein the prover claimed location is untrusted, wherein each of the plurality of verifier electronic devices may be configured to calculate a timing offset based on a location of the verifier electronic device and the prover claimed location; receiving, by the prover electronic device and from each of the plurality of verifier electronic devices, a challenge message, wherein each of the plurality of verifier electronic devices may be configured to communicate their challenge messages to prover electronic device using the timing offsets so that the challenge messages arrive at the same time in response to receiving the PPS signal in the modulated clock signal; executing, by the prover electronic device, an action using the challenge messages, resulting in an answer; and communicating, by the prover electronic device, the answer to the plurality of verifier electronic devices, wherein each of the plurality of verifier electronic devices may be configured to verify the answer and to verify a time of arrival of the answer.

In one embodiment, the duty cycle may be modified by increasing the duty cycle.

In one embodiment, the PPS signal indicates that a prover is ready to start a quantum position verification round.

In one embodiment, the action may include hashing contents of the challenge messages.

In one embodiment, the action may include measuring a quantum state of a quantum system using contents of the challenge messages.

In one embodiment, the time of arrival may be based on a distance between the location of each of the plurality of verifier electronic devices and the prover claimed location.

### BRIEF DESCRIPTION OF THE DRAWINGS

For a more complete understanding of the present invention, the objects and advantages thereof, reference is now made to the following descriptions taken in connection with the accompanying drawings in which:

FIG. 1 illustrates a device for providing ultra-low latency communication links according to an embodiment;

FIGS. 2A and 2B illustrate systems for providing ultra-low latency communication links according to embodiments;

FIG. 3 illustrates the quantum position verification scheme according to an embodiment;

FIG. 4 depicts a modulated clock signal according to an embodiment;

FIG. 5 depicts a method for modulating a clock signal with a pulse per second (PPS) signal is provided according to an embodiment;

FIG. 6 depicts a method for quantum position verification scheme using ultra-low latency communication links is provided according to an embodiment;

FIG. 7 depicts an exemplary timing diagram of the QPV process with a periodically modified duty cycle according to an embodiment;

FIG. 8 depicts a diagram of a timing delay to comply with a set timing according to an embodiment;

FIG. 9 depicts an example of QPV encoding of multiple symbols according to an embodiment;

FIG. 10 depicts an example of QPV encoding for three verifiers according to an embodiment; and

FIG. 11 depicts an exemplary computing system for implementing aspects of the present disclosure.

### DETAILED DESCRIPTION OF PREFERRED EMBODIMENTS

Embodiments are directed to systems, methods, and devices for providing ultra-low latency communication links.

In one embodiment, ultra-low latency wireless communication systems may use Field Programmable Gate Arrays (FPGA) with integrated Radio Frequency (RF) transceivers or other wired interfaces. Embodiments may provide a reduced Size, Weight, and Power (SWaP) footprint, which enables mobile and reconfigurable operation.

Embodiments may provide ultra-low latency wireless communication with integrated classical processing and RF functions that enable applications, such as QPV, with acceptable latencies.

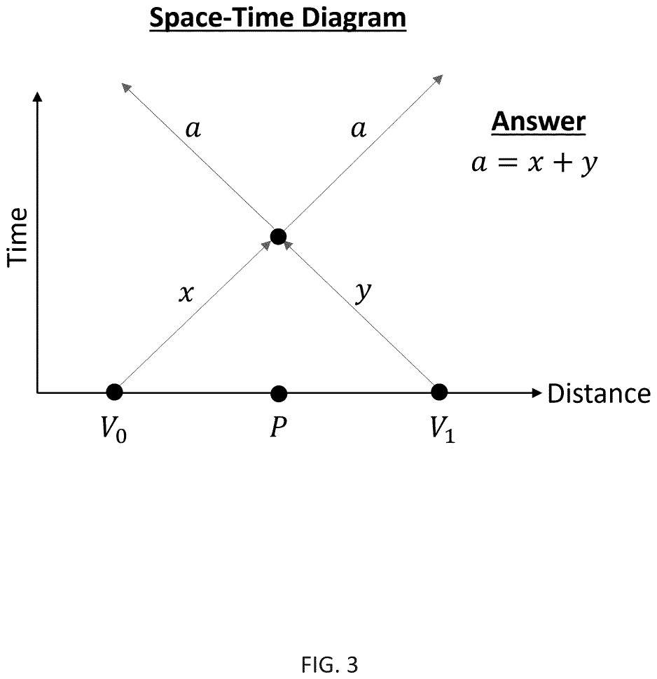

Referring to FIG. 3, an illustration of a QPV protocol is provided according to an embodiment. In QPV, ultra-low latency wireless communication may be used to determine the position of an untrusted prover (P), using two trusted verifiers, denoted as Verifier 0 (V₀) and Verifier 1 (V₁).

The QPV protocol requires that Verifier 0 transmits a challenge message (x) and Verifier 1 transmits a challenge message (y), such that they arrive simultaneously at the Prover's location. The Verifiers may coordinate their transmission times such that challenge messages (x) and (y) arrive simultaneously at the prover's claimed location. Challenge messages (x) and (y) may be selected randomly by each verifier, and may be encoded in binary.

The challenge messages (x) and (y) may include values, such as binary values.

The Prover receives the challenge messages (x) and (y), and may execute an action using the challenge messages (x) and (y). The action can only be successfully executed if both challenge messages (x) and (y) are known. Examples of actions include hashing the values of the challenge messages, measuring a quantum state using the values as a basis, etc. After execution of the action, the Prover may transmit the result of the action, such as answer (a), to the Verifiers.

The Verifiers receive the answer (a) and check both for correctness and the appropriate received time of arrival (TOA). The verifiers accept the Prover's claimed location if the correct answers are received at the expected TOA. Multiple runs of the QPV protocol may be executed.

QPV may be used in conjunction with performing real-time system control over a network, or settling financial transactions.

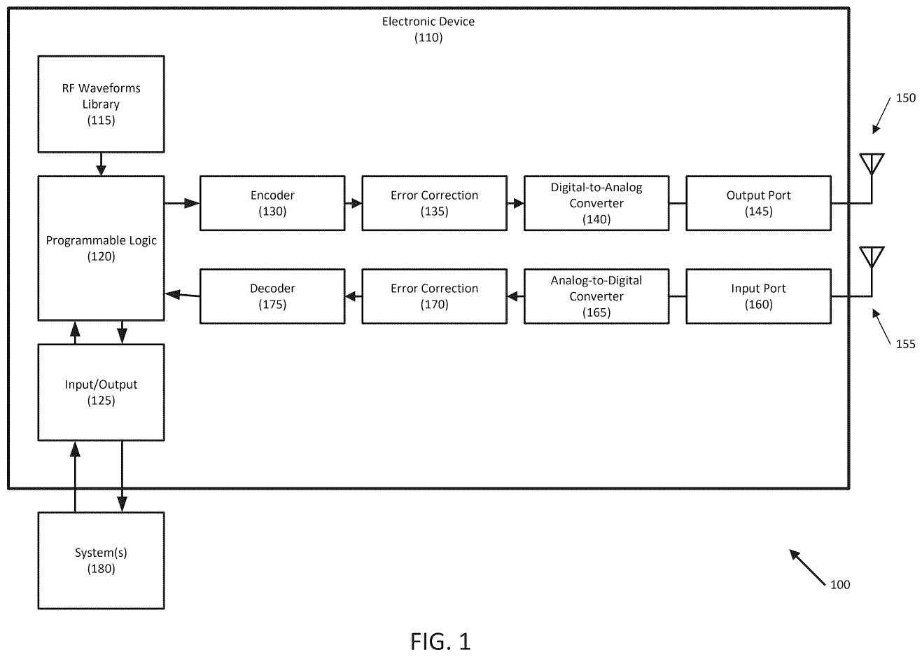

Referring to FIG. 1, a system for providing ultra-low latency communication links is disclosed according to an embodiment. System 100 may include electronic device 110, such as a field programmable gate array (FPGA), a programmable logic device (PLD), a complex programmable logic device (CPLD), an application specific integrated chip (ASIC), or custom hardware circuit, etc. Electronic device 110 may include radio frequency (RF) waveform library 115, programmable logical 120, input/output interface 125, encoder 130, error correction 135 and 170, digital-to-analog converter 140, ports 145 and 160, antennas 150 and 155, analog-to-digital converter 165, and decoder 175.

In the QPV protocol, the prover and the verifiers may use electronic devices 110.

Electronic device 110 may operate over many frequency bands, including, for example, an ISM band, a sub-6 GHz band, a mm-wave band, Ultra-Wide Band (UWB), or any other suitable frequency band.

RF waveforms library 115 may include RF waveforms (e.g., digital signals) that may be transmitted. The RF waveforms may be used to encode challenge messages (x), (y), as well as the prover's response (a). The RF waveforms are designed to multiplex multiple symbols with low rise/fall times, while also being compliant with the Federal Communications Commission (FCC) Radio Frequency (RF) spectrum bands.

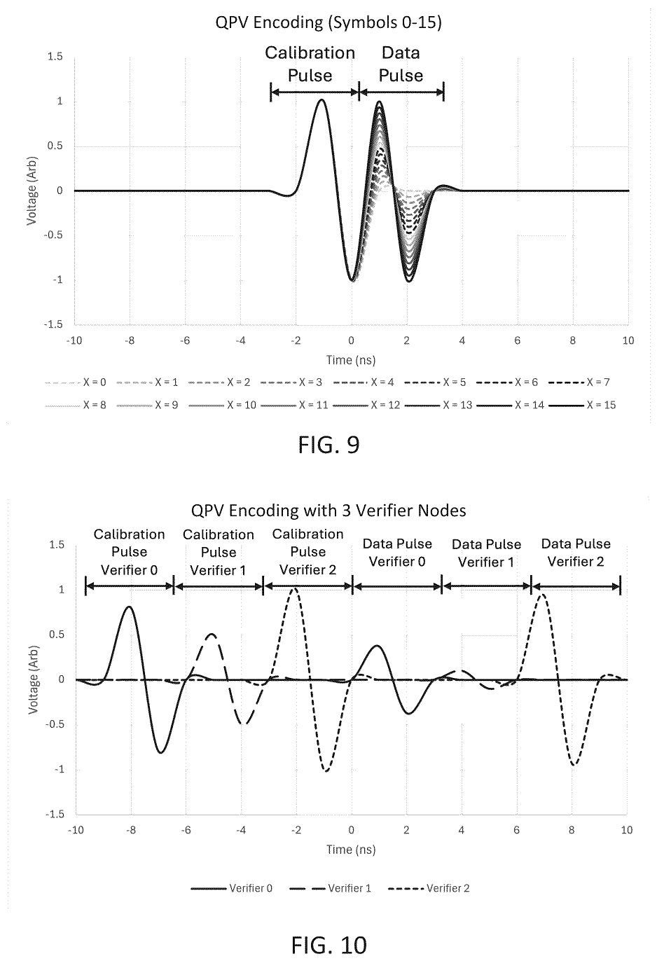

In one embodiment, encoder 130 may an select an appropriate RF waveform based on the value of the signal being transmitted. For example, if the value being transmitted is one of 16 possible values between 0 and 15, the amplitude of the second peak is equal to C*X/15, where C is the amplitude of calibration pulse (i.e., the first pulse in the RF waveform), and X is the value to be transmitted in a data pulse. This is illustrated in FIG. 9. Note, the data pulse is repeated twice (one positive and one negative) which allows for error detection. For example, if there is a difference in amplitude between the positive data pulse and the negative data pulse, an error may be detected.

Decoder 175 may measure the received digital signal. In practice, wireless communication channel loss is present (due to 1/R² distance loss and attenuation due to obstacles), therefore the received pulse will be attenuated. The amplitude of the received calibration pulse is equal to C′, where C′<C. Thus, the amplitude of the initial calibration pulse may be different from that of the received calibration pulse. The decoded value

$$X = m \times \frac{15}{{c}^{′}} ,$$

m is the measured data signal amplitude.

The RF waveforms in RF waveform library 115 may be used to multiplex values (x) and (y), may support a high data rate, and may enable error correction. The RF waveforms may provide encodings for UWB transmission that are tailored to the QPV protocol. For example, an encoding basis of values of 16 unique values from X=0 to X=15, including an initial calibration pulse from −2 ns to 0 ns may be used to calibrate the received signal strength and Analog-to-Digital Converter (ADC) offsets (both positive and negative). An example is depicted in FIG. 9. Since this calibration pulse is the same for all waveforms, there is no information in the calibration pulse, and thus the QPV start time begins at 0 ns.

The encoding is based on the strength normalized into 16 amplitude bins from 0 ns to 2 ns, with the encoding value repeated twice (to enable basic error detection). This approach allows for one of 16 encoding symbols to be communicated within 1 ns with error detection within another 1 ns.

This approach can be extended to include full error correction by repeating the encoding value three times (e.g., communication in 1 ns with error detection and correction taking an additional 2 ns). If error detection/correction is not desired, the encoding can only be sent once.

Since QPV protocols require more than one verifier, the RF waveforms enables communication to be multiplexed from multiple verifier sources. This can in principle be performed using frequency multiplexing (e.g., each verifier source uses a different base period). Frequency multiplexing, however, requires additional signal post-processing time, e.g., performing computationally complex Fast Fourier Transforms (FFT). Since the positional uncertainty for the prover's location depends on the total processing time (signal reception plus decoding time), multiplexing is used, which reduces decoding time by avoiding FFTs. Thus, the signals from each verifier, starting with the calibration pulse, followed by the encoded data from each verifier, may be multiplexed. The verifiers coordinate such that their messages arrive nearly simultaneously but are interleaved together. The data can be repeated once to support error detection or repeated twice to support full error correction.

A notional example for three verifiers is presented in FIG. 10. In this example, Verifier 0 transmits (X=7), Verifier 1 transmits (Y=3) and Verifier 2 transmits (Z=14). The calibration pulse from Verifier 0 occurs between-9 ns and −6 ns, the calibration pulse for Verifier 1 occurs between −6 ns and −3 ns, and the calibration pulse for Verifier 2 occurs between −3 ns and 0 ns. Note that in this example, the calibration pulse amplitudes from each verifier are not equal, due to the different channel losses present between the prover and each verifier node.

The different channel losses could be due either to different distances (e.g., 1/R² signal loss) between each verifier and the prover or varying attenuation due to practical obstacles (e.g., buildings, vehicles terrain) between each verifier and the prover. The data pulse from Verifier 0 occurs between 0 ns and +3 ns, the data pulse for Verifier 1 occurs between +3 ns and +6 ns, and the data pulse for Verifier 2 occurs between +6 ns and +9 ns. Note for this example, a +1 ns guard band is implemented to prevent intersymbol interference (ISI) between verifier nodes.

Decoding may be performed by comparing the data amplitude with the calibration pulse amplitude for each verifier to identify the data bin value. Without loss of generality, this approach can be extended to arbitrary number of verifier nodes.

Programmable logic 120 may comprise firmware that may form the central control system for the low-latency link. In one embodiment, programmable logic 120 may include logic to implement a protocol, such as the QPV protocol. For example, programmable logic 120 may generate a challenge message (for a verifier) or an answer (for a prover) and may send them to encoder 130.

Programmable logic 120 may include code to implement a time synchronization protocol using a single digital signal. In general, a first signal often provides a clock signal, and a second signal provides a pulse per second (PPS) signal. PPS signals are signals with sharp rising and/or falling edges that repeat once per second, and are used to provide synchronization among multiple devices or applications. In embodiments, the clock signal may be modulated to embed the PPS. Thus, the clock signal and the PPS signal may be sent in a single signal.

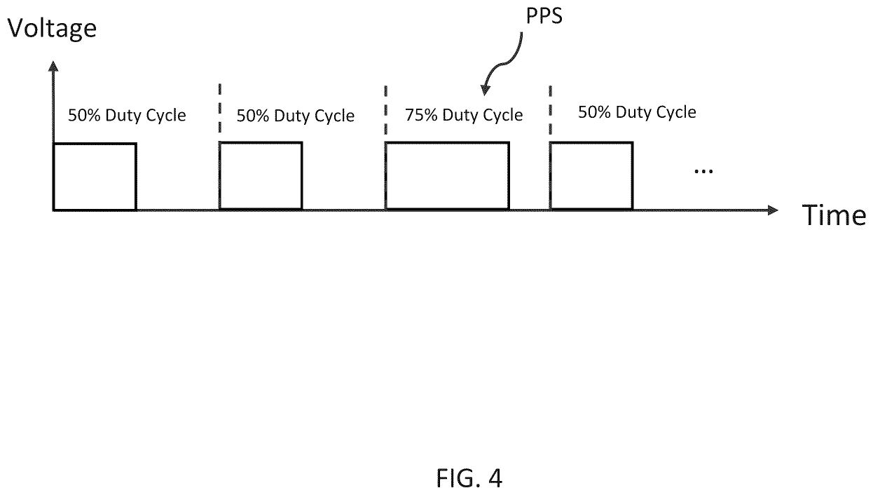

An example is illustrated in FIG. 4. As illustrated, the clock duty cycle is periodically modulated (e.g. 75% versus 50%) to embed the PPS signal. The PPS signal may be recovered by any device by identifying the modulated duty cycle of the clock signal. In one embodiment, the PPS signal may be used as a “starter gun” to provide global time synchronization for other electronic devices 110.

Programmable logic 120 may further control the computation provided by system 180, such as specifying the use of a hash function in responding to the challenge messages, quantum system measurements, etc.

Programmable logic 120 may further provide double-clocked data streaming, in which data is clocked in/out at both the rising and falling edges of a system clock, which doubles the data rate. For example, for a clock rate of 600 kHz, data can be transmitted at 1.2 GHz.

Encoder 130 may convert a message (e.g., a binary challenge message or answer) into an appropriate raw time-domain RF waveform for transmission. In one embodiment, encoder 130 may select the RF waveform from RF waveform library 115 to transmit based on the intended binary information to send.

For example, encoder 130 may encode message(s) using RF waveforms such that multiple bits of the message can be represented in the same waveform.

Error correction module 135 may change/modify the RF waveform such that a transmission error could be detected/corrected after being received by the prover. Next, these digital signals may be sent to Digital-to-Analog converter 140 that produces a voltage signal which is sent to port 145 for wired or wireless transmission to the prover.

Decoder 175 may convert a received raw time-domain RF waveform into, for example, a binary challenge message or answer. In one embodiment, decoder 175 may measure the received waveform and determine the digital data that was sent.

For example, decoding involves comparing the received signal to the library of RF waveforms to recover the message(s).

Error correction modules 135 and 170 may modify/analyze the raw transmitted RF waveform with additional signatures to detect and compensate when bit error(s) have occurred during signal transmission.

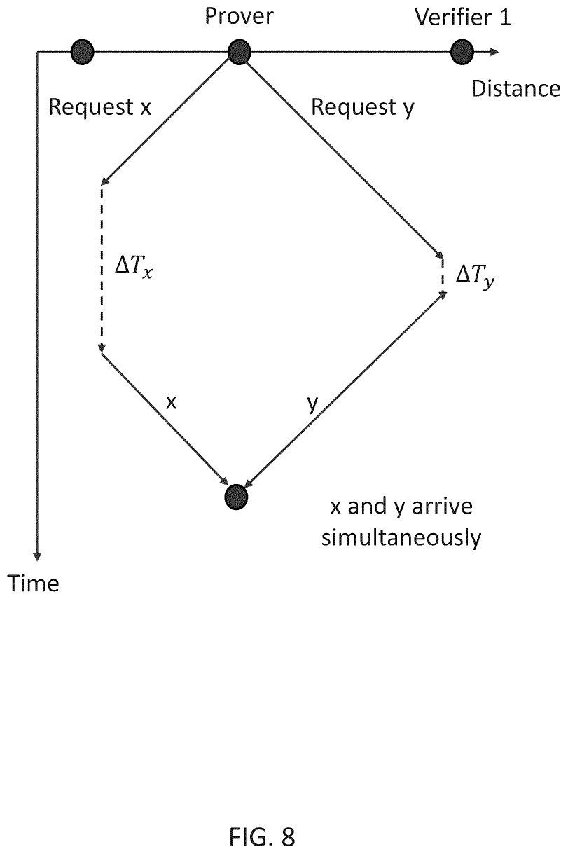

In one embodiment, the RF waveforms (e.g., FIGS. 8 and 9) allow for error detection because the data payload is repeated twice—once positive and once negative. To error check, the prover may simply check if the two repeated data payloads match for consistency. Additionally, if the data payload is repeated three times (not shown), then the prover may perform error correction by keeping the answer in the majority of the payloads.

Digital-to-analog converter 140 may convert the digital signal to an analog signal for transmission via port 145, such as one or more SubMiniature version A (SMA) ports, one or more General Purpose Input/Output (GPIO) ports, etc. for transmission via antennas 150 and 155, or by low-latency wired communication.

For example, coaxial RF cables that provide a high-propagation velocity (e.g., approximately 88% speed of light) may be used. As another example, hollow-core fibers (HCF) may be used.

Antennas 150 and 155 may be part of the same transceiver.

Input/output interface 125 may provide an interface between electronic device 110 and system(s) 180. System(s) 180 may provide data to be transmitted, may consume data that is received, may execute an action using the data that is received, and/or may control the transmission/reception of data.

Within the context of the QPV protocol, systems 180 may interact with quantum states. For example, systems 180 may be quantum devices, and may interface via quantum links (e.g., direct optical fiber connections, direct satellite connections, etc.).

Systems 180 may also include quantum sources/devices that may provide sources for quantum state preparation, quantum state transformations, and/or quantum measurements, etc. Quantum resources such as quantum entanglement may be used.

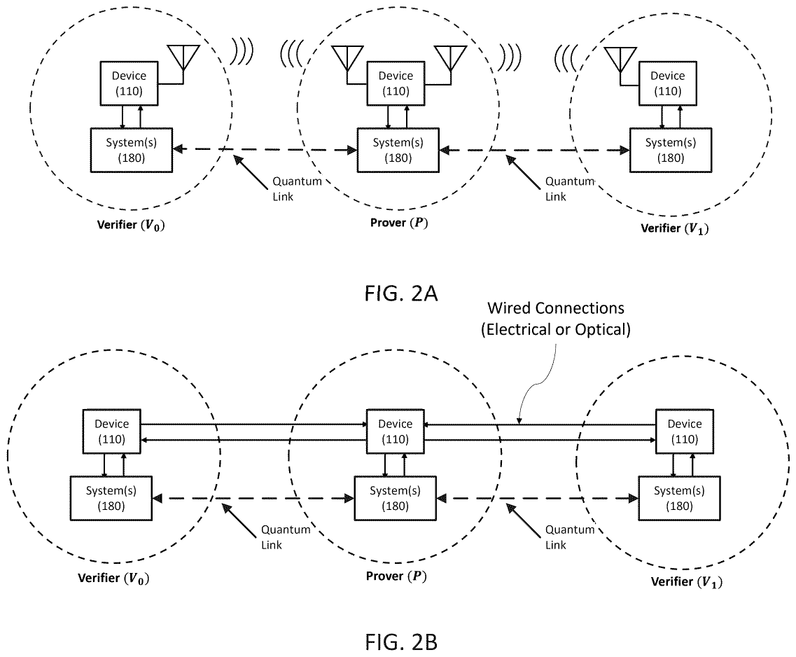

FIG. 2A illustrates a plurality of electronic devices 110 in wireless communication, and FIG. 2B illustrates a plurality of electronic devices 110 in wired communication. It should be noted that a combination of wired and wireless communications may be used as is necessary and/or desired.

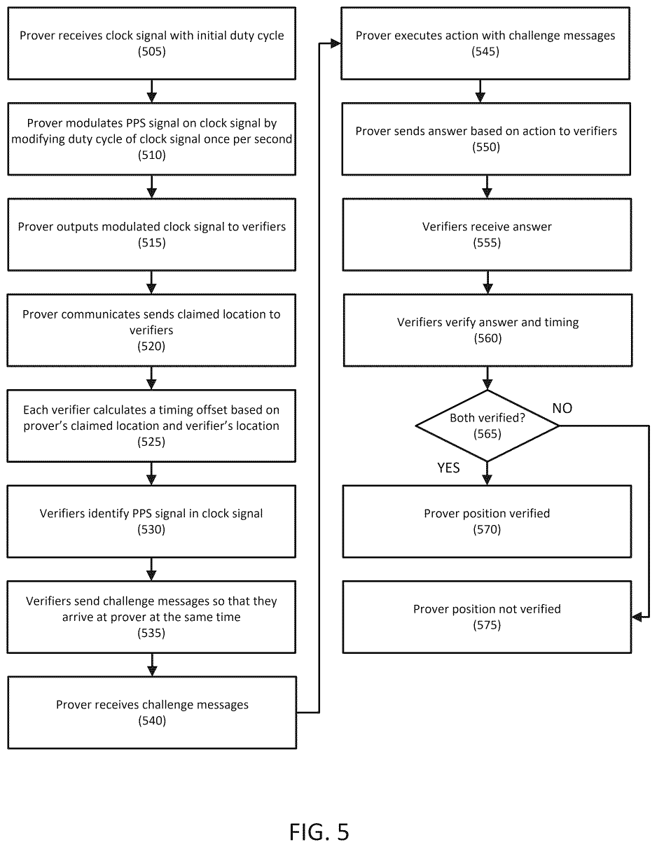

Referring to FIG. 5, a method for modulating a clock signal with a PPS signal is provided according to an embodiment.

In step 505, programmable logic on a prover electronic device may control programable logic to generate a clock signal with an initial duty cycle.

In step 510, the programmable logic may modify the duty cycle of one of the cycles once per second. In one embodiment, the programmable logic may modify the high signal to increase its duty cycle from, for example, 50% to 75%.

In step 515, the programmable logic may cause the clock signal with the periodically modified duty cycle to be broadcast to a plurality of electronic devices, such as to a plurality of verifiers.

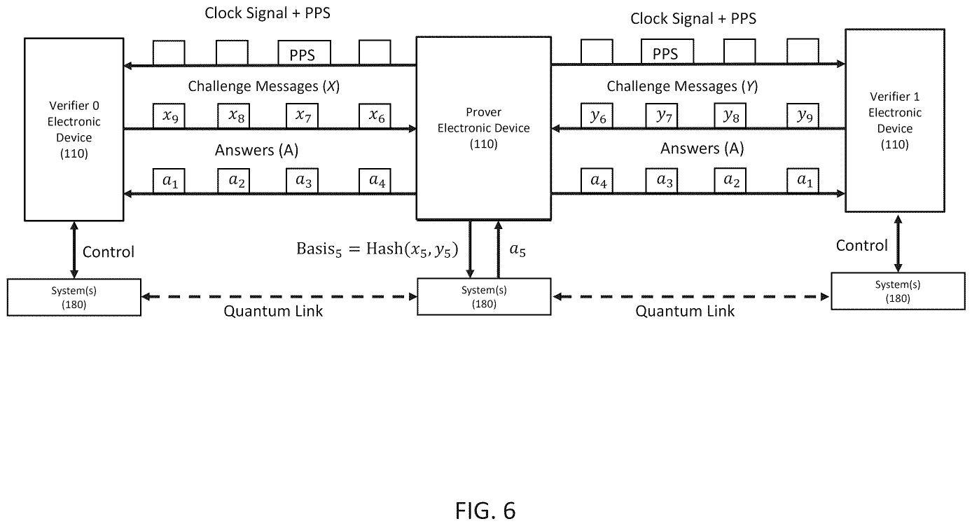

For example, the rising edge of the modulated clock signal corresponds to the prover being ready to start each QPV round. Thus, the frequency of the modulated clock is set to match the rate of QPV rounds, as illustrated in FIG. 6. In addition, the PPS signal is embedded (modulated) by modulating the duty cycle of the clock ready signal as illustrated in FIG. 4. This scheme requires that the prover transmits a ready clock signal every second, corresponding to the PPS signal. Thus, the rate of QPV rounds must be an integer frequency in Hz.

In step 520, the prover may claim to be at a given location, and the prover electronic device may communicate its claimed location to a plurality of verifier electronic devices. The location of the prover is assumed to be untrusted (e.g., unconfirmed).

In step 525, the verifier electronic devices may calculate relative timing offsets based on the prover's claimed location and the locations of each verifier. The location of the verifiers is assumed to be trusted.

The relative timing offsets may be calculated by the verifiers by determining the distance between each verifier location and the prover's claimed location. From there, the differences in distance may be divided by the speed of light to determine the timing offset for at least one of the verifiers. Thus, the verifier that is furthest from the prover will communicate its challenge message first, and then the next furthest verifier will communicate its challenge message with a timing offset (i.e., a delay) based on the additional distance between it and the prover, and so on. This results in the challenge messages at the prover at the same time.

In step 530, the verifiers may identify the rising edge of the modulated clock signal as a start to the QPV round, and in step 535, may generate their challenge messages and may adjust timing of sending challenge messages so that they arrive at prover at the same time. In one embodiment, the timing may be based on the distance between the prover and the verifier.

In step 540, the prover may receive the challenge messages, and in step 545, may execute an action with challenge messages, such as interacting with quantum systems. In one embodiment, the action may be specified by the control software on the prover electronic device.

In step 550, the prover may send an answer based on action to the verifiers, and in step 555, the verifiers may receive the answer.

In step 560, the verifiers verify that the correct answer was received and arrival time of the answer corresponded to the prover's claimed location. If, in step 565, both the answer and the timing are verified, in step 570, the prover position is verified. If the answer or the timing is not verified, in step 575, the prover position is not verified.

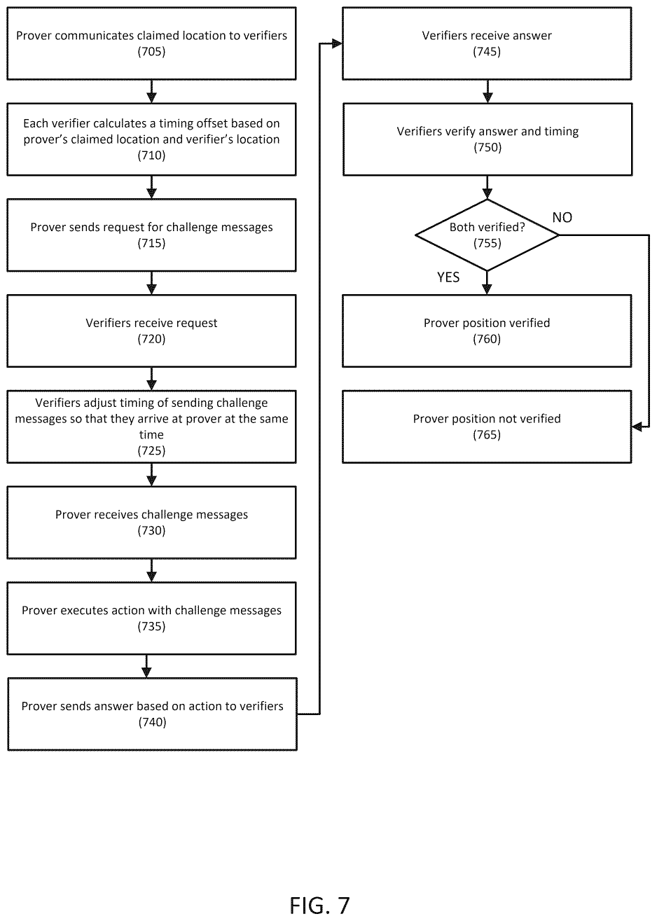

Referring to FIG. 7, a method for quantum position verification scheme using ultra-low latency communication links is provided according to an embodiment.

In step 705, a prover may claim to be at a given location, and a prover electronic device may communicate this to a plurality of verifier electronic devices. The location of the prover is assumed to be untrusted (e.g., unconfirmed).

In step 710, the verifier electronic devices may calculate relative timing offsets based on the prover's claimed location and the locations of each verifier. The location of the verifiers is assumed to be trusted.

The relative timing offsets may be calculated by the verifiers by determining the distance between each verifier location and the prover's claimed location. From there, the differences in distance may be divided by the speed of light to determine the timing offset for at least one of the verifiers. Thus, the verifier that is furthest from the prover will communicate its challenge message first, and then the next furthest verifier will communicate its challenge message with a timing offset (i.e., a delay) based on the additional distance between it and the prover, and so on. This results in the challenge messages at the prover at the same time.

In step 715, as part of a quantum position verification process, the prover may send a request for challenge messages to the verifiers, and in step 720, the verifiers may receive the request.

In step 725, the verifiers may generate their challenge messages and may adjust timing of sending challenge messages so that they arrive at prover at the same time.

An illustration of the timing delay is provided in FIG. 8. The start of each round is indicated by the rising edge of a clock signal transmitted by the prover. In general, the rising edge of the clock signal will arrive at each verifier at different times. Verifiers V0 and V1 transmit challenge messages x and y, respectively, to the Prover. Additionally, the verifiers adjust the transmission times such that the challenge messages x and y arrive simultaneously at the prover's claimed location. The interaction that the prover will have with the quantum system will depend on having access to both challenge values x and y, and is only possible if the prover is at the claimed location. If the prover is located at a different position, they will still learn of values x and y, but at a later time which can be detected in the QPV protocol.

In step 730, the prover may receive the challenge messages, and in step 735, may execute an action with challenge messages, such as interacting with quantum systems. In one embodiment, the action may be specified by the control software on the prover electronic device.

In step 740, the prover may send an answer based on action to the verifiers, and in step 745, the verifiers may receive the answer.

In step 750, the verifiers verify that the correct answer was received and arrival time of the answer corresponded to the prover's claimed location. If, in step 755, both the answer and the timing are verified, in step 760, the prover position is verified. If the answer or the timing is not verified, in step 765, the prover position is not verified.

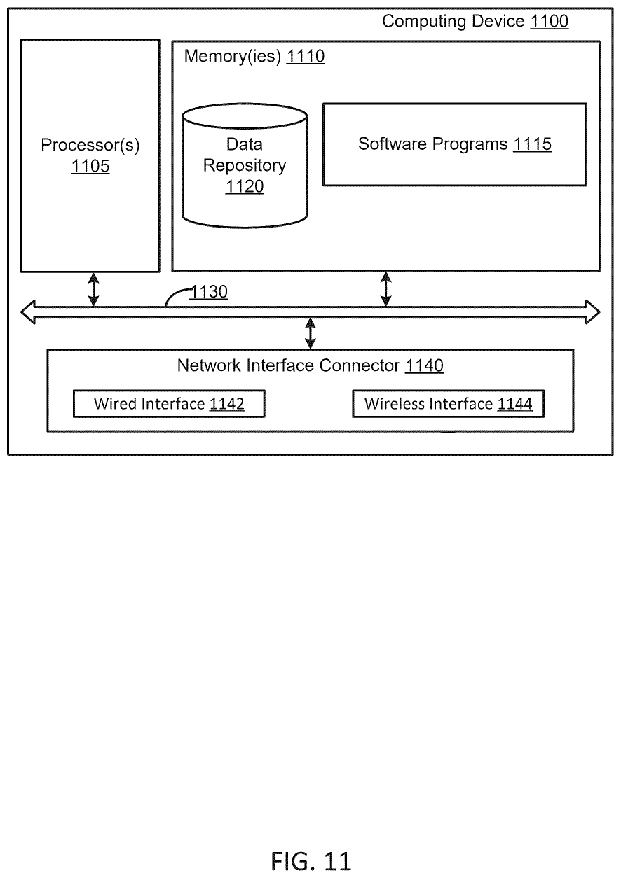

FIG. 11 depicts an exemplary computing system for implementing aspects of the present disclosure. FIG. 11 depicts exemplary computing device 1100. Computing device 1100 may represent the system components described herein. Computing device 1100 may include processor 1105 that may be coupled to memory 1110. Memory 1110 may include volatile memory. Processor 1105 may execute computer-executable program code stored in memory 1110, such as software programs 1115. Software programs 1115 may include one or more of the logical steps disclosed herein as a programmatic instruction, which may be executed by processor 1105. Memory 1110 may also include data repository 1120, which may be nonvolatile memory for data persistence. Processor 1105 and memory 1110 may be coupled by bus 1130. Bus 1130 may also be coupled to one or more network interface connectors 1140, such as wired network interface 1142 or wireless network interface 1144. Computing device 1100 may also have user interface components, such as a screen for displaying graphical user interfaces and receiving input from the user, a mouse, a keyboard and/or other input/output components (not shown).

Although several embodiments have been disclosed, it should be recognized that these embodiments are not exclusive to each other and features from one embodiment may be used with others.

Hereinafter, general aspects of implementation of the systems and methods of embodiments will be described.

Embodiments of the system or portions of the system may be in the form of a “processing machine,” such as a general-purpose computer, for example. As used herein, the term “processing machine” is to be understood to include at least one processor that uses at least one memory. The at least one memory stores a set of instructions. The instructions may be either permanently or temporarily stored in the memory or memories of the processing machine. The processor executes the instructions that are stored in the memory or memories in order to process data. The set of instructions may include various instructions that perform a particular task or tasks, such as those tasks described above. Such a set of instructions for performing a particular task may be characterized as a program, software program, or simply software.

In one embodiment, the processing machine may be a specialized processor.

In one embodiment, the processing machine may be a cloud-based processing machine, a physical processing machine, or combinations thereof.

As noted above, the processing machine executes the instructions that are stored in the memory or memories to process data. This processing of data may be in response to commands by a user or users of the processing machine, in response to previous processing, in response to a request by another processing machine and/or any other input, for example.

As noted above, the processing machine used to implement embodiments may be a general-purpose computer. However, the processing machine described above may also utilize any of a wide variety of other technologies including a special purpose computer, a computer system including, for example, a microcomputer, mini-computer or mainframe, a programmed microprocessor, a micro-controller, a peripheral integrated circuit element, a CSIC (Customer Specific Integrated Circuit) or ASIC (Application Specific Integrated Circuit) or other integrated circuit, a logic circuit, a digital signal processor, a programmable logic device such as a FPGA (Field-Programmable Gate Array), PLD (Programmable Logic Device), PLA (Programmable Logic Array), or PAL (Programmable Array Logic), or any other device or arrangement of devices that is capable of implementing the steps of the processes disclosed herein.

The processing machine used to implement embodiments may utilize a suitable operating system.

It is appreciated that in order to practice the method of the embodiments as described above, it is not necessary that the processors and/or the memories of the processing machine be physically located in the same geographical place. That is, each of the processors and the memories used by the processing machine may be located in geographically distinct locations and connected so as to communicate in any suitable manner. Additionally, it is appreciated that each of the processor and/or the memory may be composed of different physical pieces of equipment. Accordingly, it is not necessary that the processor be one single piece of equipment in one location and that the memory be another single piece of equipment in another location. That is, it is contemplated that the processor may be two pieces of equipment in two different physical locations. The two distinct pieces of equipment may be connected in any suitable manner. Additionally, the memory may include two or more portions of memory in two or more physical locations.

To explain further, processing, as described above, is performed by various components and various memories. However, it is appreciated that the processing performed by two distinct components as described above, in accordance with a further embodiment, may be performed by a single component. Further, the processing performed by one distinct component as described above may be performed by two distinct components.

In a similar manner, the memory storage performed by two distinct memory portions as described above, in accordance with a further embodiment, may be performed by a single memory portion. Further, the memory storage performed by one distinct memory portion as described above may be performed by two memory portions.

Further, various technologies may be used to provide communication between the various processors and/or memories, as well as to allow the processors and/or the memories to communicate with any other entity; i.e., so as to obtain further instructions or to access and use remote memory stores, for example. Such technologies used to provide such communication might include a network, the Internet, Intranet, Extranet, a LAN, an Ethernet, wireless communication via cell tower or satellite, or any client server system that provides communication, for example. Such communications technologies may use any suitable protocol such as TCP/IP, UDP, or OSI, for example.

As described above, a set of instructions may be used in the processing of embodiments. The set of instructions may be in the form of a program or software. The software may be in the form of system software or application software, for example. The software might also be in the form of a collection of separate programs, a program module within a larger program, or a portion of a program module, for example. The software used might also include modular programming in the form of object-oriented programming. The software tells the processing machine what to do with the data being processed.

Further, it is appreciated that the instructions or set of instructions used in the implementation and operation of embodiments may be in a suitable form such that the processing machine may read the instructions. For example, the instructions that form a program may be in the form of a suitable programming language, which is converted to machine language or object code to allow the processor or processors to read the instructions. That is, written lines of programming code or source code, in a particular programming language, are converted to machine language using a compiler, assembler or interpreter. The machine language is binary coded machine instructions that are specific to a particular type of processing machine, i.e., to a particular type of computer, for example. The computer understands the machine language.

Any suitable programming language may be used in accordance with the various embodiments. Also, the instructions and/or data used in the practice of embodiments may utilize any compression or encryption technique or algorithm, as may be desired. An encryption module might be used to encrypt data. Further, files or other data may be decrypted using a suitable decryption module, for example.

As described above, the embodiments may illustratively be embodied in the form of a processing machine, including a computer or computer system, for example, that includes at least one memory. It is to be appreciated that the set of instructions, i.e., the software for example, that enables the computer operating system to perform the operations described above may be contained on any of a wide variety of media or medium, as desired. Further, the data that is processed by the set of instructions might also be contained on any of a wide variety of media or medium. That is, the particular medium, i.e., the memory in the processing machine, utilized to hold the set of instructions and/or the data used in embodiments may take on any of a variety of physical forms or transmissions, for example. Illustratively, the medium may be in the form of a compact disc, a DVD, an integrated circuit, a hard disk, a floppy disk, an optical disc, a magnetic tape, a RAM, a ROM, a PROM, an EPROM, a wire, a cable, a fiber, a communications channel, a satellite transmission, a memory card, a SIM card, or other remote transmission, as well as any other medium or source of data that may be read by the processors.

Further, the memory or memories used in the processing machine that implements embodiments may be in any of a wide variety of forms to allow the memory to hold instructions, data, or other information, as is desired. Thus, the memory might be in the form of a database to hold data. The database might use any desired arrangement of files such as a flat file arrangement or a relational database arrangement, for example.

In the systems and methods, a variety of “user interfaces” may be utilized to allow a user to interface with the processing machine or machines that are used to implement embodiments. As used herein, a user interface includes any hardware, software, or combination of hardware and software used by the processing machine that allows a user to interact with the processing machine. A user interface may be in the form of a dialogue screen for example. A user interface may also include any of a mouse, touch screen, keyboard, keypad, voice reader, voice recognizer, dialogue screen, menu box, list, checkbox, toggle switch, a pushbutton or any other device that allows a user to receive information regarding the operation of the processing machine as it processes a set of instructions and/or provides the processing machine with information. Accordingly, the user interface is any device that provides communication between a user and a processing machine. The information provided by the user to the processing machine through the user interface may be in the form of a command, a selection of data, or some other input, for example.

As discussed above, a user interface is utilized by the processing machine that performs a set of instructions such that the processing machine processes data for a user. The user interface is typically used by the processing machine for interacting with a user either to convey information or receive information from the user. However, it should be appreciated that in accordance with some embodiments of the system and method, it is not necessary that a human user actually interact with a user interface used by the processing machine. Rather, it is also contemplated that the user interface might interact, i.e., convey and receive information, with another processing machine, rather than a human user. Accordingly, the other processing machine might be characterized as a user. Further, it is contemplated that a user interface utilized in the system and method may interact partially with another processing machine or processing machines, while also interacting partially with a human user.

It will be readily understood by those persons skilled in the art that embodiments are susceptible to broad utility and application. Many embodiments and adaptations of the present invention other than those herein described, as well as many variations, modifications and equivalent arrangements, will be apparent from or reasonably suggested by the foregoing description thereof, without departing from the substance or scope.

Accordingly, while the embodiments of the present invention have been described here in detail in relation to its exemplary embodiments, it is to be understood that this disclosure is only illustrative and exemplary of the present invention and is made to provide an enabling disclosure of the invention. Accordingly, the foregoing disclosure is not intended to be construed or to limit the present invention or otherwise to exclude any other such embodiments, adaptations, variations, modifications, or equivalent arrangements.

What is claimed is:

1. An electronic device, comprising:
programmable logic that is configured to generate a first digital signal;
an encoder that is configured to encode the first digital signal using a first RF waveform, wherein the first RF waveform is selected based on a value of the first digital signal and comprises an initial calibration pulse, and the first digital signal is encoded with a positive amplitude and a negative amplitude;
a digital-to-analog converter that is configured to convert the encoded first digital signal to an encoded first analog signal;
an output port that is configured to output the encoded first analog signal to a second electronic device over a low-latency connection;
an input port that is configured to receive an encoded second analog signal from the second electronic device over the low-latency connection;
an analog-to-digital converter that is configured to convert the encoded second analog signal to an encoded second digital signal;
a decoder that is configured to extract the encoded second digital signal into a second digital signal by measuring the encoded second digital signal and a received calibration pulse in the encoded second digital signal; and
an input/output interface that is configured to provide the second digital signal to a system that is configured to execute an action based on the second digital signal.

2. The electronic device of claim 1, wherein the electronic device comprises a field programmable gate array, or a programmable logic device, application specific integrated chip.

3. The electronic device of claim 1, wherein the programmable logic is further configured to generate a clock signal and to modulate the clock signal with a pulse per second (PPS) signal by modifying a duty cycle of the clock signal once per second, and to communicate the modulated clock signal to another electronic device.

4. The electronic device of claim 3, wherein the duty cycle is modified by increasing the duty cycle.

5. The electronic device of claim 3, wherein the PPS signal indicates that a prover is ready to start a quantum position verification round.

6. The electronic device of claim 1, further comprising at least one antenna that is configured to receive the encoded first analog signal from the output port and to communicate the encoded first analog signal over the low-latency connection, and to receive the encoded second analog signal from the low-latency connection and provide the encoded second analog signal to the input port.

7. The electronic device of claim 1, further comprising:
an error correction module that is configured to detect an error in the encoded first digital signal by comparing the positive amplitude and the negative amplitude of the encoded first digital signal; and/or to detect an error in the encoded second digital signal by comparing a positive amplitude and the negative amplitude of the encoded second digital signal.

8. The electronic device of claim 1, wherein the low-latency connection comprises a hollow core fiber and/or a coaxial RF cable.

9. The electronic device of claim 1, wherein the system comprises a quantum source, and the system executes an action on the second digital signal by executing a quantum state transformation and/or a quantum measurement.

10. A method, comprising:
communicating, by a prover electronic device and to a plurality of verifier electronic devices, a prover claimed location, wherein the prover claimed location is untrusted, wherein each of the plurality of verifier electronic devices is configured to calculate a timing offset based on a location of the verifier electronic device and the prover claimed location;
communicating, by the prover electronic device and to the plurality of verifier electronic devices, a request for challenge messages;
receiving, by the prover electronic device and from each of the plurality of verifier electronic devices, a challenge message, wherein each of the plurality of verifier electronic devices is configured to communicate their challenge messages to prover electronic device using the timing offsets so that the challenge messages arrive at the same time;
executing, by the prover electronic device, an action using the challenge messages, resulting in an answer; and
communicating, by the prover electronic device, the answer to the plurality of verifier electronic devices, wherein each of the plurality of verifier electronic devices is configured to verify the answer and to verify a time of arrival of the answer.

11. The method of claim 10, wherein the action comprises hashing contents of the challenge messages.

12. The method of claim 10, wherein the action comprises measuring a quantum state of a quantum system using contents of the challenge messages.

13. The method of claim 10, wherein the time of arrival is based on a distance between the location of each of the plurality of verifier electronic devices and the prover claimed location.

14. A method, comprising:
generating, by a prover electronic device, a modulated clock signal with a pulse per second (PPS) signal by modifying a duty cycle of a clock signal once per second;
communicating, by the prover electronic device, the modulated clock signal to a plurality of verifier electronic devices;
communicating, by the prover electronic device and to the plurality of verifier electronic devices, a prover claimed location, wherein the prover claimed location is untrusted, wherein each of the plurality of verifier electronic devices is configured to calculate a timing offset based on a location of the verifier electronic device and the prover claimed location;
receiving, by the prover electronic device and from each of the plurality of verifier electronic devices, a challenge message, wherein each of the plurality of verifier electronic devices is configured to communicate their challenge messages to prover electronic device using the timing offsets so that the challenge messages arrive at the same time in response to receiving the PPS signal in the modulated clock signal;
executing, by the prover electronic device, an action using the challenge messages, resulting in an answer; and
communicating, by the prover electronic device, the answer to the plurality of verifier electronic devices, wherein each of the plurality of verifier electronic devices is configured to verify the answer and to verify a time of arrival of the answer.

15. The method of claim 14, wherein the duty cycle is modified by increasing the duty cycle.

16. The method of claim 14, wherein the PPS signal indicates that a prover is ready to start a quantum position verification round.

17. The method of claim 14, wherein the action comprises hashing contents of the challenge messages.

18. The method of claim 14, wherein the action comprises measuring a quantum state of a quantum system using contents of the challenge messages.

19. The method of claim 14, wherein the time of arrival is based on a distance between the location of each of the plurality of verifier electronic devices and the prover claimed location.
